(19) United States
(12) Patent Application Publication
(10) Pub. No.: US 2004/0108580 A1
(43) Pub. Date: Jun. 10, 2004

(54) Leadless semiconductor packaging structure with inverted flip chip and methods of manufacture

(75) Inventors: Kim Hwee Tan, Singapore (SG); Roman Perez, Singapore (SG); Kee Kwang Lau, Singapore (SG); Alex Chew, Singapore (SG); Antonio Dimaano, Singapore (SG)

Correspondence Address: STEPHEN B. ACKERMAN, 28 DAVIS AVENUE, POUGHKEEPSIE, NY, 12603, US

(73) Assignee: Advanpack Solutions Pte. Ltd.

(21) Appl. No.: 10/314,716

(22) Filed: Dec. 9, 2002

(51) Int. Cl. H01L 23/02

(52) U.S. Cl. 257/678

(57) ABSTRACT

A semiconductor chip packaging structure is described. The structure comprising of a semiconductor chip interconnected to a recessed lead frame and the resultant assembly encapsulated in a molding compound. The final product is a reverse mounted semiconductor chip in a leadless quad flat pack configuration. A second embodiment allows for the semiconductor chip backside to be exposed for thermal enhancements. Manufacturing methods are also described for the two embodiments disclosed.

### FIELD OF INVENTION

The present invention relates in general to the packaging of semiconductor devices, integrated circuits or hybrid chips. More specifically to semiconductor packages that have highly space efficient packaging designs. Several methods of manufacturing these packages are also disclosed.

### BACKGROUND OF THE INVENTION

The following three U.S. patents relate to semiconductor chip packaging designs.

U.S. Pat. No. 5,604,376 dated Feb. 18, 1997 issued to W. R. Hamburgen et. al., shows a molded semiconductor chip wire bonded to a lead frame while the backside of the chip is exposed for thermal enhancement.

U.S. Pat. No. 5,776,800 dated Jul. 7, 1998 issued to W. R. Hamburgen et al., describes a method for fabricating a molded semiconductor package where a semiconductor chip is wire bonded to a lead frame and molded with the backside of the chip exposed.

U.S. Pat. No. 5,986,334 dated Nov. 16, 1999 issued to S. G. Lee, titled “SEMICONDUCTOR PACKAGE HAVING LIGHT, SIMPLE AND COMPACT STRUCTURE”, describes four designs for interconnecting a semiconductor chip to a lead frame with a flip chip design for thermal enhancements.

With the development of VLSI technology in the semiconductor field and the application of the technology to products and systems that require space efficient components the need for semiconductor chip packages with compact structures has become primary.

Semiconductor chip packaging, or first level packaging, needs to address the following requirements for each application:

Provide the required number of electrical signal interconnections to the semiconductor chip.

Provide the required number of electrical power supply interconnections to the semiconductor chip.

Have the necessary wiring structure for interconnecting the signal and power lines to and from the chip to the next level of package, typically a printed circuit board.

Provide a means of removing thermal energy generated by the circuits of the semiconductor chip.

Provide a structure to mechanically support and protect the chip from environmental contaminants.

These demands have been met by various first level package designs. Both ceramic and plastic materials have been used as the basic structure with metal lead frames and/or wire bonding utilized for the interconnections. Wire bonding to the chip terminals has been the main method of interconnecting to the chip terminals. Flip chip designs utilizing copper, gold, or solder bumps have also been used for interconnecting to the chip terminals.

The initial dual-in-line DIP packages shown in FIG. 1 (prior art), utilized both ceramic and plastic structures with back bonded semiconductor chips wire bonded to lead frames. Main drawbacks to this design were the use of two sides of the package for interconnections and the use of leads that required plated through holes in the next level of package. This packaging structure has a very low efficiency of space utilization resulting in higher time delays and negatively affecting system performance.

A semiconductor package that also requires plated through holes is the pin grid array PGA package show in FIG. 2 (prior art). The PGA package utilizes mainly a ceramic body with internal metallurgy connecting the chip terminals to the external pins. Both wire bonded and flip chip bumped chips are used for chip interconnections. The main advantage of the PGA package is the higher utilization of the area for interconnections as it is an aerial array interconnection design.

The advent of surface mount technology SMT where interconnections of the first level package to the printed circuit card or board that do not require plated through holes resulted in the development of packages that utilized the total periphery of the package for interconnecting leads as shown in FIG. 3 (prior art). The quad-flat-pack QFP design shown in FIG. 3 (prior art) utilizes both ceramic and plastic body structure and wire bonding or flip chips to mount and interconnect the semiconductor chips. Surface mount and use of the four sides of the package for interconnect resulted in enhanced space utilization and electrical performance.

To further enhance space utilization and improve electrical characteristics the external leads of the package were incorporated into the ceramic or plastic body structure. A ceramic version of the leadless chip carrier LCC is shown in FIG. 4 (prior art). The LCC design has enhanced space properties and electrical characteristics. The design lacks the ability to contact the semiconductor chip with thermal enhancements. In addition the ceramic body requires that a hermetic metal seal be provided for environmental protection of the semiconductor chip. The manufacturing method for the ceramic LCC is complicated resulting in high product costs.

### SUMMARY OF THE INVENTION

Accordingly it is an object of one or more embodiments of the present invention to provide a semiconductor chip first level package that has the ability to house, mechanically support, and interconnect the semiconductor chip signal and power terminals to the terminals that are externally accessible for interconnecting to the next level of package.

It is a further object of one or more embodiments of the present invention to have the capability for adding thermal enhancements by providing access to the back side of the chip for use in applications that require thermal enhancement; i. e., heat sinks.

An additional objective of the invention is that the resultant package design have a compact structure that provides for increased space efficiency and better system performance at the system level.

The package design should also have the ability to interconnect semiconductor chips that have been designed with wire bonded interconnections without redesign of the semiconductor chip or package layout.

Another objective of the present invention is to provide a process for manufacturing the semiconductor package that is simple, cost efficient, and provides quality product.

The above objectives are achieved by the present invention by providing a design and method of manufacture for semiconductor chip packaging structure with fully encapsulated inverted flip chip and as a second embodiment a design and method of manufacture for a semiconductor chip package with an exposed inverted flip chip backside.

An embodiment of the present invention is shown in FIGS. 5A, 5B. FIG. 5A is a cross sectional view of the package structure where the semiconductor chip 10 is reverse flip chip bonded to a recessed lead frame 14. The semiconductor chip and lead frame assembly is encapsulated in a molding compound 16. The lead frame 14 has exposed contacts for interconnecting to the next level of package as shown in FIG. 5B.

Another embodiment of the present invention is shown in FIGS. 6A, 6B. The semiconductor chip 10 is reverse flip chip bonded to a recessed lead frame 14. The semiconductor chip and lead frame assembly is encapsulated in a molding compound 16. This embodiment allows the backside of the semiconductor chip 10 to be exposed for thermal enhancements. This is accomplished by different methods during fabrication.

### BRIEF DESCRIPTION OF THE DRAWINGS

The present invention will be more clearly understood from the following description taken in conjunction with the accompanying drawings in which like reference numerals designate similar or corresponding elements, regions and portions and in which:

FIG. 1 is a conventional DIP module of the prior art.

FIG. 2 is a conventional PGA module of the prior art.

FIG. 3 is a conventional QFP module of the prior art.

FIG. 4 is a conventional LCC module of the prior art.

FIG. 5A is a cross sectional view of the first preferred embodiment of the inverted flip chip package of the present invention.

FIG. 5B is a bottom view of the first preferred embodiment of the inverted flip chip package of the present invention.

FIG. 6A is a cross sectional view of the second preferred embodiment of the inverted flip chip package of the present invention.

FIG. 6B is a bottom view of the second preferred embodiment of the inverted flip chip package of the present invention.

FIG. 7 shows the method of joining the semiconductor chip to the recessed lead frame of the first preferred embodiment of the invention.

FIG. 8 shows the molding of the semiconductor chip and lead frame assembly of the first preferred embodiment of the invention.

FIG. 9 shows the grinding process of the first preferred embodiment of the invention.

FIG. 10 shows the method of joining the semiconductor chip to the lead frame of the second embodiment of the invention.

FIG. 11 shows the molding of the semiconductor chip and lead frame assembly of the second embodiment of the invention.

FIG. 12 shows the grinding process of the second preferred embodiment of the invention.

FIG. 13 shows the alternate method of manufacturing the second preferred embodiment of the invention.

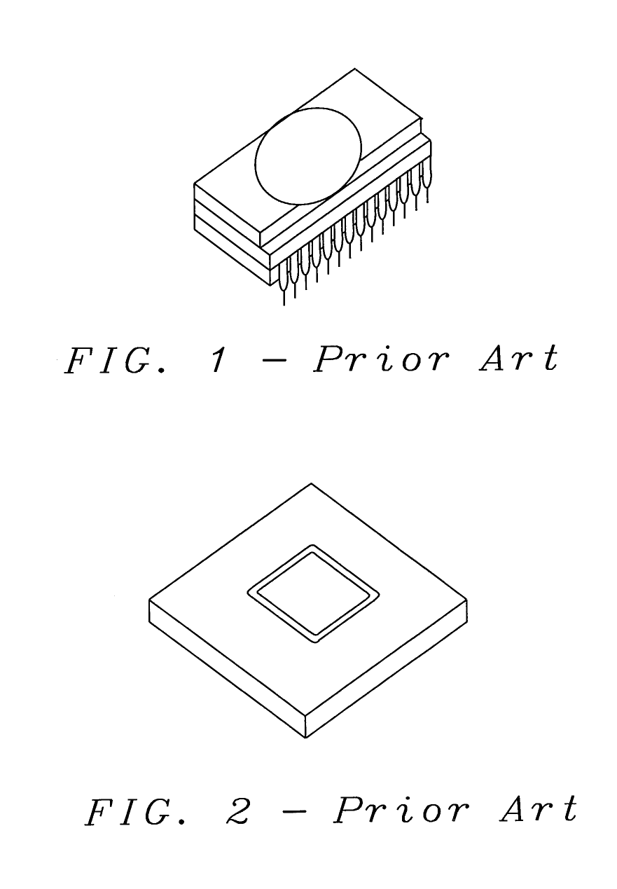

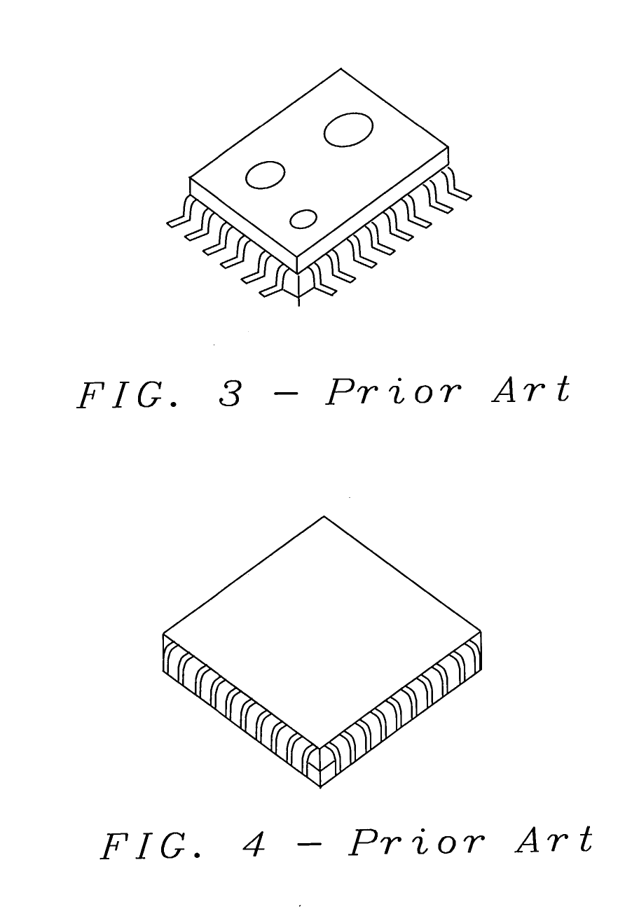

### DETAILED DESCRIPTION OF THE PREFERRED EMBODIMENT

The utilization of VLSI semiconductor chips in commercial electronic products such as cameras, camcorders, DVD players, etc., has demanded that semiconductor packages be highly space efficient in their designs. In addition, military applications require light weight space efficient packaging structures.

To satisfy these requirements semiconductor packaging structures have been developed to provide the increasing demand for input-output interconnections, the high thermal usage of the semiconductor chips, while protecting the semiconductor chips from the environment. These packaging structures have utilized both plastic and ceramic materials for the main structure of the package, and utilized wire bonding, solder bumps, and lead frames for interconnecting the semiconductor chip input-output and power terminals to the external connections.

The present invention discloses a semiconductor packaging structure and methods of manufacture that utilize a semiconductor chip with input-output and power terminals connected to a recessed lead frame and the assembly encapsulated in a plastic compount.

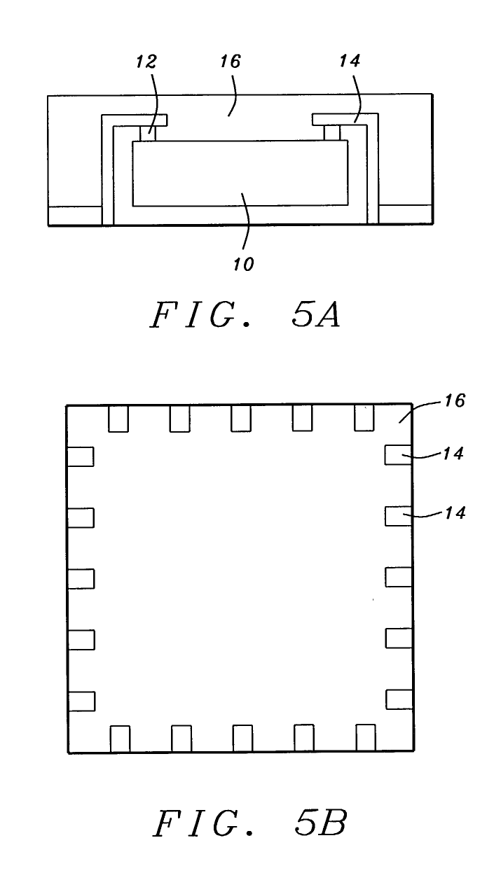

The present invention is shown in FIG. 5A and FIG. 5B. The semiconductor chip 10 that includes solder ball, solder tip or copper bumps for interconnects 12 is connected to a recessed lead frame 14 and encapsulated in a plastic compound 16. The encapsulant is molded in a manner that allows the external leads of the lead frame 14 to be accessible for interconnect to the next level.

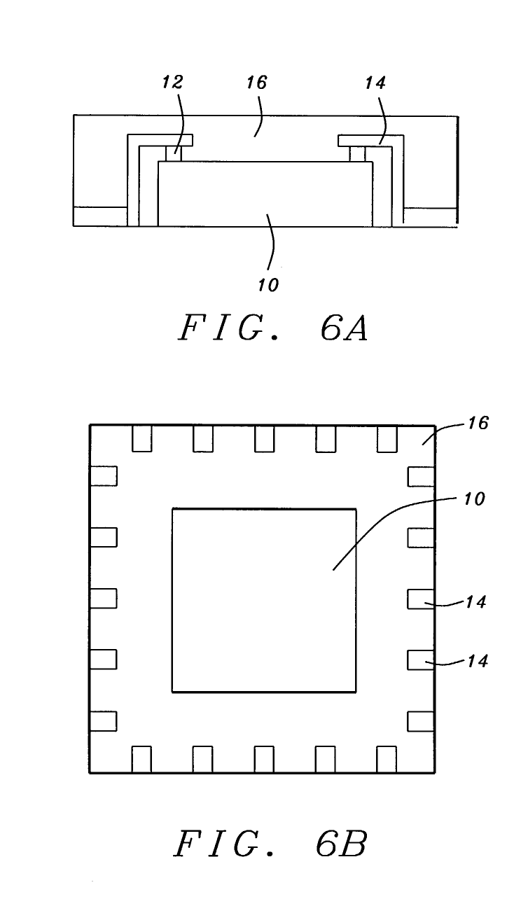

A second embodiment of the present invention is shown in FIG. 6A and FIG. 6B. The semiconductor chip 10 that includes solder bail, solder tip or copper bumps for interconnects 12 is connected to a recessed lead frame 14 and encapsulated in a plastic compound 16. The encapsulant is molded in a manner that allows the external leads of the lead frame 14 to be accessible for interconnect to the next level. This embodiment of the present invention also allows for the backside of the semiconductor chip to be accessible for the addition of thermal enhancements.

The semiconductor chip package inverted flip chip structures disclosed in the first and second embodiments of the present invention satisfy the demands of electronic systems for a space efficient semiconductor package. In addition the compact structure provides enhanced electrical properties such as low signal time of flight. The inverted flip chip packaging structure also allows the utilization of semiconductor chips designed for packages using wire bonding without having to redesign the signal and power routing of the semiconductor chips. The disclosed packaging structures may be used with semiconductor chips of different thicknesses by varying the depth of the recess in the lead frame. This feature results in overall packaging structures that are less than 1 mm. in thickness.

The method of manufacture of the reverse flip chip semiconductor package of the present invention and disclosed herein consists of the following steps:

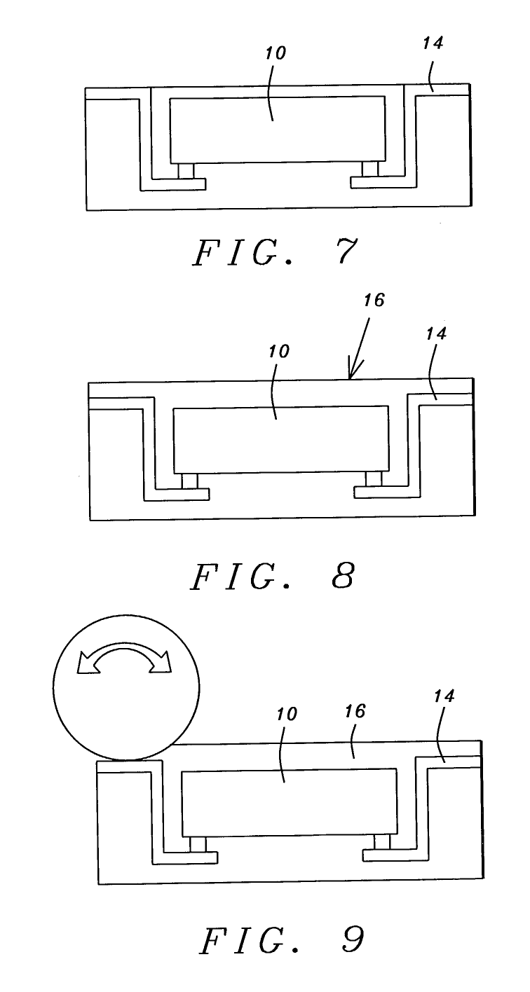

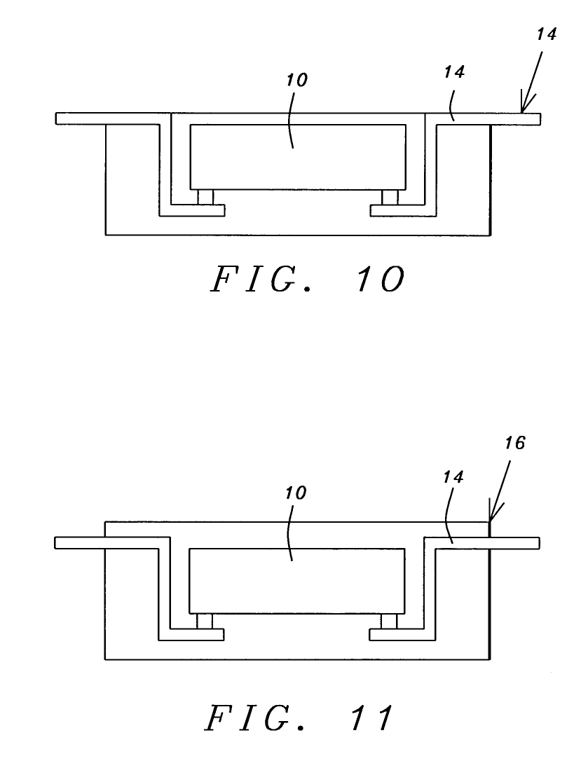

In the first embodiment of the present invention the reverse flip chip semiconductor is fully encapsulated as shown in FIG. 5A. A conductive metal lead frame 14, FIG. 7 with recessed inner leads is metallurgically bonded to the bumped semiconductor chip 10. The assembly is molded in a plastic compound 16, FIG. 8. After curing of the molding compound a grinding process is employed to remove the molding compound from the external leads of the lead frame 14 FIG. 9.

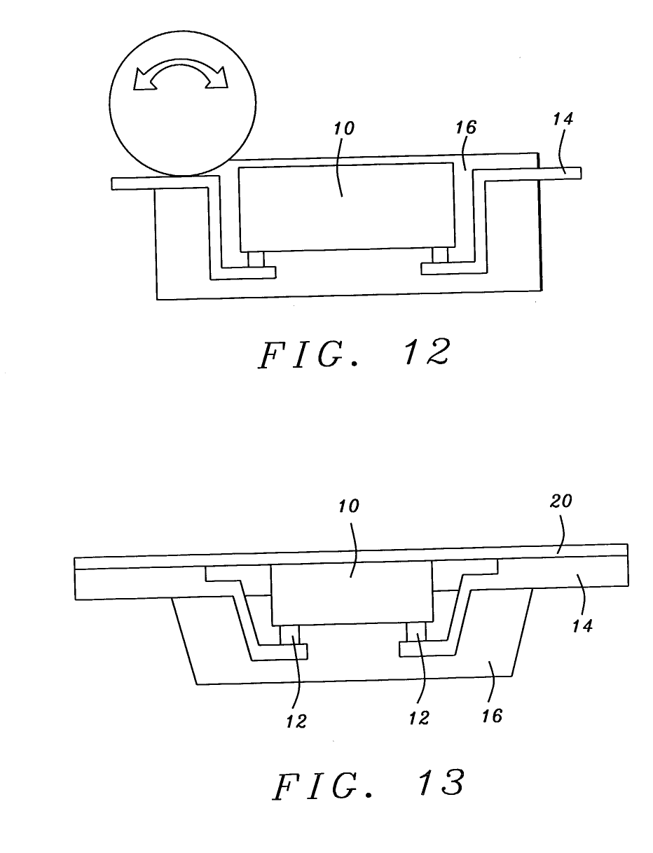

In the second embodiment of the present invention the reverse flip chip semiconductor chip shown in FIG. 6A is processed in a similar as the fully encapsulated embodiment with the exception that the lead frame 14 FIG. 10 and FIG. 11 has a recess that is shallower and allows the backside of the semiconductor chip 10 to be exposed in the grinding operation FIG. 12.

Another method for obtaining the structure described in the second embodiment of the present invention is to utilize a thin film 20 during the molding process FIG. 13 that restricts the molding compound from covering the backside of the semiconductor chip and the external contacts of the lead frame.

Advantages of the Present Invention

The advantages of one or more embodiments of the present invention include a semiconductor chip packaging structure that is highly space efficient, provides enhanced electrical properties, may be thermally enhanced, may be utilized in packaging semiconductor chips of different size, and is design transparent in packaging previously wire bonded semiconductor chips. The methods of manufacturing this structure are simple and cost effective.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof.

What is claimed is:

1. A semiconductor chip packaging structure comprising:
a reverse mounted semiconductor chip;
a recessed conductive metal alloy lead frame interconnected to input-output and power terminals of said semiconductor chip;
a molded encapsulant fully surrounding said semiconductor chip and said lead frame;
and solderable leads for said recessed metal lead frame, for external interconnections.

2. The semiconductor packaging structure of claim 1 wherein the lead frame comprises a copper Cu alloy.

3. The semiconductor packaging structure of claim 1 wherein interconnections of said semiconductor chip comprise a solder alloy shaped into solder balls or columns.

4. The semiconductor packaging structure of claim wherein the semiconductor chip interconnections of said semiconductor chip comprise of copper Cu or metal pillars.

5. The semiconductor packaging structure of claim 1 wherein the lead frame is recessed to a variable depth in the chip interconnection area.

6. The semiconductor packaging structure of claim 1 wherein the overall thickness of the structure is less than approximately 1 mm.

7. The semiconductor packaging structure of claim 1 wherein the semiconductor chip used is designed for a wire bonded application.

8. A semiconductor chip packaging structure comprising:
a reverse mounted semiconductor chip;
a recessed conductive metal alloy lead frame interconnected to input-output and power terminals of said semiconductor chip;
a molded encapsulant surrounding said semiconductor chip and said lead frame assembly, wherein the backside of the semiconductor chip, and outer input-output and power leads, are exposed.

9. The semiconductor packaging structure of claim 8 wherein the lead frame is a copper Cu alloy.

10. The semiconductor packaging structure of claim 8 wherein interconnections of said semiconductor chip comprise a solder alloy shaped into solder balls or columns.

11. The semiconductor packaging structure of claim 8 wherein the semiconductor chip interconnections of said semiconductor chip comprise of copper Cu or metal pillars.

12. The semiconductor packaging structure of claim 8 wherein the lead frame is recessed to a variable depth in the chip interconnection area.

13. The semiconductor packaging structure of claim 8 wherein the overall thickness of the structure is less than approximately 1 mm.

14. The semiconductor packaging structure of claim 8 wherein the semiconductor chip used is designed for a wire bonded application.

15. A method for creating a reverse mounted semiconductor chip package comprising the steps of:
providing a recessed lead frame;
interconnecting a semiconductor chip to the recessed lead frame;
fully encapsulating the chip and recessed lead frame to form a lead frame assembly;
grinding the lead frame assembly to expose outer lead frame input-output and power contacts;
and solder plating of the exposed outer lead frame input-outer and power contacts.

16. A method for creating a reverse mounted semiconductor chip package comprising the steps of:
providing a recessed lead frame;
interconnecting a semiconductor chip to the recessed lead frame;
fully encapsulating the chip and recessed lead frame to form a lead frame assembly;
grinding the lead frame assembly to expose backside of the said semiconductor chip and the outer contacts of the lead frame;
and providing solder plating of the exposed lead frame contacts.

17. The method of claim 16 wherein a plastic film is used in the molding process to allow for the backside of the said semiconductor chip and the outer contacts of the lead frame to be exposed.
